(19) United States
(12) Patent Application Publication
(10) Pub. No.: US 2016/0032064 A1
(43) Pub. Date: Feb. 4, 2016

(54) ENCAPSULANT SHEET FOR SOLAR CELL

(71) Applicant: SUMITOMO CHEMICAL COMPANY, LIMITED, Tokyo (JP)

(72) Inventor: Hiroaki YODA, lchihara-shi (JP)

(21) Appl. No.: 14/812,209

(22) Filed: Jul. 29, 2015

(30) Foreign Application Priority Data
Jul. 31, 2014 (JP) 2014-156028

(51) Int. Cl. C08J 5/18; H01L 31/048

(52) U.S. Cl. CPC C08J 5/18; H01L 31/0481; H01L 31/0488; C08J 2323/08; C08J 2423/08

(57) ABSTRACT

An encapsulant sheet for a solar cell contains not less than 91% but less than 99% by mass of an ethylene-unsaturated ester copolymer (A), more than 1% but not more than 9% by mass of an olefin resins (B), 0.001 parts to 5 parts by mass of silicon dioxide and 0.001 to 0.5 parts by mass of a silane coupling agent, where the sum total of the content of the ethylene-unsaturated ester copolymer (A) and the content of the olefin resin (B) is taken as 100% by mass. The content of the silicon dioxide and the content of the silane coupling agent are relative to the total content of the ethylene-unsaturated ester copolymer (A) and the content of the olefin resin (B) being taken as 100% by mass. The encapsulant sheet is excellent in insulating property, storage stability, transparency, and durability of adhesion to glass.

### BACKGROUND OF THE INVENTION

1. Technical Field

The present invention relates to an encapsulant sheet for a solar cell.

2. Background Art

In recent years, solar cells are becoming more prevalent as devices suitable for use of renewable energy.

Generally, a solar cell is composed of a light-receiving-surface protective member made of glass, a solar cell element (power generation element), an encapsulant sheet, and a backsheet, and a sheet comprising an ethylene-vinyl acetate copolymer, an ethylene-a-olefin copolymer, and/or an ethylene acetic acid vinyl glycidyl methacrylate copolymer has been used as the encapsulant sheet (patent documents 1, 2).

### PRIOR ART DOCUMENT

Patent Document 1: JP-A-2000-183385

Patent Document 2: JP-A-4-325531

### SUMMARY OF THE INVENTION

### Problems to Be Solved by the Invention

However, the encapsulant sheets disclosed in the patent documents are insufficient in insulating property, storage stability, and transparency, and none of them cannot maintain adhesion to glass for a long time.

The present invention has been devised in view of the above-mentioned problems, an object of the present invention is to provide an encapsulant sheet for a solar cell, the sheet being excellent in insulating property, storage stability, transparency, and durability of adhesion to glass.

### Means for solving the Problems

The present invention relates to an encapsulant sheet for a solar cell comprising:

not less than 91% by mass but less than 99% by mass of an ethylene-unsaturated ester copolymer (A) that comprises monomer units derived from ethylene and monomer units derived from at least one unsaturated ester selected from the group consisting of vinyl acetate, vinyl propionate, methyl acrylate, ethyl acrylate, butyl acrylate, methyl methacrylate, and ethyl methacrylate, and that fails to comprise monomer units derived from acrylic acid, methacrylic acid, or any unsaturated carboxylic glycidyl ester, wherein the content of the monomer units derived from ethylene is 60% by mass to 80% by mass and the content of the monomer units derived from the at least one unsaturated ester is 20% by mass to 40% by mass where the content of the monomer units derived from ethylene and the content of the monomer units derived from the at least one unsaturated ester are each relative to the sum total of the two contents being taken as 100% by mass,

more than 1% by mass but not more than 9% by mass of at least one olefin resin (B) selected from the group consisting of an ethylene-(meth) acrylic acid copolymer comprising monomer units derived from ethylene and monomer units derived from acrylic acid or methacrylic acid and an ethylene-unsaturated carboxylic glycidyl ester copolymer comprising monomer units derived from ethylene and monomer units derived from an unsaturated carboxylic glycidyl ester, wherein the content of the ethylene-unsaturated ester copolymer (A) and the content of the at least one olefin resin (B) are each relative to the sum total of the two contents being taken as 100% by mass,

0.001 parts by mass to 5 parts by mass of silicon dioxide, and

0.001 parts by mass to 0.5 parts by mass of a silane coupling agent, wherein the content of the silicon dioxide and the content of the silane coupling agent are each relative to the combined content of the ethylene-unsaturated ester copolymer (A) and the at least one olefin resin (B) being taken as 100% by mass.

According to the present invention, there can be obtained an encapsulant sheet for a solar cell, the sheet being excellent in insulating property, storage stability, and transparency and being capable of maintaining adhesive to glass over a long time.

### MODE FOR CARRYING OUT THE INVENTION

### [Ethylene-Unsaturated Ester Copolymer (A)]

The ethylene-unsaturated ester copolymer (A) to be used for the present invention is a copolymer comprising monomer units derived from ethylene and monomer units derived from at least one unsaturated ester selected from the group consisting of vinyl acetate, vinyl propionate, methyl acrylate, ethyl acrylate, butyl acrylate, methyl methacrylate, and ethyl methacrylate. It is noted that the ethylene-unsaturated ester copolymer (A) contains no monomer units derived from acrylic acid, methacrylic acid, and unsaturated carboxylic glycidyl esters.

As the ethylene-unsaturated ester copolymer (A), one copolymer may be used, or alternatively two or more copolymers may be used together.

Examples of the ethylene-unsaturated ester copolymer (A) include an ethylene-vinyl acetate copolymer, an ethylene-vinyl propionate copolymer, an ethylene-methyl acrylate copolymer, an ethylene-ethyl acrylate copolymer, an ethylene-butyl acrylate copolymer, an ethylene-methyl methacrylate copolymer, an ethylene-ethyl methacrylate copolymer, and an ethylene-vinyl acetate-methyl methacrylate copolymer.

The ethylene-unsaturated ester copolymer (A) preferably comprises at least one copolymer selected from the group consisting of an ethylene-vinyl acetate copolymer, an ethylene-methyl acrylate copolymer, an ethylene-methyl methacrylate copolymer, and an ethylene-vinyl acetate-methyl methacrylate copolymer, and an ethylene-vinyl acetate copolymer and an ethylene-methyl methacrylate copolymer are particularly preferable.

The content of the monomer units derived from ethylene in the ethylene-unsaturated ester copolymer (A) is 60% by mass to 80% by mass, and from the viewpoint of the transparency of an encapsulant sheet fora solar cell, it is preferably not less than 65% by mass, more preferably not less than 67% by mass, and preferably is not more than 75% by mass, more preferably not more than 74% by mass.

The content of the monomer units derived from the unsaturated ester in the ethylene-unsaturated ester copolymer (A) is 20% by mass to 40% by mass, and from the viewpoint of the transparency of an encapsulant sheet for a solar cell, it is preferably not less than 25% by mass, more preferably not less than 26% by mass, and preferably is not more than 35% by mass, more preferably not more than 33% by mass. It is noted that said content of the monomer units derived from ethylene and said content of the monomer units derived from the unsaturated ester are relative to 100% by mass in total of these two contents.

When the ethylene-unsaturated ester copolymer (A) has monomer units derived from two or more unsaturated esters, the content of the monomer units derived from the unsaturated esters is the sum total of the contents of the monomer units derived from the individual unsaturated esters contained in the ethylene-unsaturated ester copolymer (A).

The content of the monomer units derived from ethylene and the content of the monomer units derived from the unsaturated ester in the ethylene-unsaturated ester copolymer (A) can be determined by a method known in the art, for example, the method disclosed in JIS K7192 or an infrared spectroscopic method.

The melt flow rates (hereinafter abbreviated as MFR) of the ethylene-unsaturated ester copolymer (A) is preferably not less than 4 g/10 min, more preferably not less than 5 g/10 min, and preferably is not more than 50 g/10 min, more preferably not more than 40 g/10 min. MFR is measured under conditions including a temperature of 190° C. and a load of 21.18 N by the method specified in JIS K7210-1995.

The molecular weight distribution (Mw/Mn) of the ethylene-unsaturated ester copolymer (A) is preferably not less than 2, more preferably not less than 2.5, even more preferably not less than 3, and preferably is not more than 8, more preferably not more than 5, even more preferably not more than 4.5. It is noted that Mw denotes a polystyrene-equivalent weight average molecular weight and Mn denotes a polystyrene-equivalent number average molecular weight. The polystyrene-equivalent weight average molecular weight and the polystyrene-equivalent number average molecular weight are determined by gel permeation chromatographic measurement.

The polyethylene-equivalent weight average molecular weight of the ethylene-unsaturated ester copolymer (A) is preferably not less than 40000, more preferably not less than 50000, and preferably is not more than 80000, more preferably not more than 70000. The polyethylene-equivalent weight average molecular weight is a product of the polystyrene-equivalent weight average molecular weight and a ratio of Q factors of polyethylene and polystyrene (17.7/41.3).

Examples of a method for producing the ethylene-unsaturated ester copolymer (A) include a high-pressure polymerization method, a slurry polymerization method, a solution polymerization method, a bulk polymerization method, and a gas phase polymerization method.

### [Olefin Resin (B)]

The olefin resin (B) to be used for the present invention is at least one resin selected from the group consisting of an ethylene-(meth) acrylic acid copolymer comprising monomer units derived from ethylene and monomer units derived from acrylic acid or methacrylic acid (henceforth referred to as resin (B3)) and an ethylene-unsaturated carboxylic glycidyl ester copolymer comprising monomer units derived from ethylene and monomer units derived from an unsaturated carboxylic glycidyl ester (henceforth referred to as resin (B4)). The term “(meth) acrylic acid” denotes acrylic acid and methacrylic acid comprehensively. The resin (B3) does not have monomer units derived from an unsaturated carboxylic glycidyl ester, whereas the resin (B4) does not have monomer units derived from acrylic acid or methacrylic acid.

From the viewpoint of the transparency of an encapsulant sheet fora solar cell, the content of the monomer units derived from ethylene in the resin (B3) is preferably not more than 95% by mass, more preferably not more than 93% by mass, even more preferably not more than 91% by mass.

From the viewpoint of the transparency of an encapsulant sheet fora solar cell, the content of the monomer units derived from acrylic acid or methacrylic acid in the resin (B3) is preferably not less than 3% by mass, more preferably not less than 5% by mass, even more preferably not less than 7% by mass, still even more preferably not less than 9% by mass, and from the viewpoint of the handling property of an encapsulant sheet for a solar cell, it is preferably not more than 40% by mass, more preferably not more than 35% by mass. It is noted that the sum total of said content of the monomer units derived from ethylene and said content of the monomer units derived from acrylic acid or methacrylic acid is taken as 100% by mass.

The content of the monomer units derived from ethylene and the content of the monomer units derived from acrylic acid or methacrylic acid in the resin (B3) can be determined by a method known in the art, for example, an infrared spectroscopic method.

The resin (B3) may further have monomer units derived from an unsaturated ester excluding an unsaturated carboxylic glycidyl ester. Examples of such an unsaturated ester include vinyl acetate, vinyl propionate, methyl acrylate, ethyl acrylate, butyl acrylate, methyl methacrylate, and ethyl methacrylate. As the resin (B3), an ethylene acrylic acid copolymer or an ethylene methacrylic acid copolymer is preferable.

Examples of the unsaturated carboxylic glycidyl ester that constitutes the resin (B4) include glycidyl acrylate and glycidyl methacrylate.

From the viewpoint of the transparency of an encapsulant sheet for a solar cell, the content of the monomer units derived from ethylene in the resin (B4) is preferably not less than 60% by mass, more preferably not less than 65% by mass, and from the viewpoint of the transparency of an encapsulant sheet for a solar cell, it is preferably not more than 98% by mass, more preferably not more than 90% by mass, even more preferably not more than 80% by mass, still even more preferably not more than 75% by mass.

From the viewpoint of the transparency of an encapsulant sheet for a solar cell, the content of the monomer units derived from the unsaturated carboxylic glycidyl ester in the resin (B4) is preferably not less than 2% by mass, more preferably not less than 10% by mass, even more preferably not less than 20% by mass, still even more preferably not less than 25% by mass, and from the viewpoint of the transparency of an encapsulant sheet for a solar cell, it is preferably not more than 40% by mass, more preferably not more than 35% by mass. It is noted that the sum total of said content of the monomer units derived from ethylene and said content of the monomer units derived from the unsaturated carboxylic glycidyl ester is taken as 100% by mass.

The content of the monomer units derived from ethylene and the content of the monomer units derived from the unsaturated carboxylic glycidyl ester in the resin (B4) can be determined by a method known in the art, for example, an infrared spectroscopic method.

The resin (B4) may further have monomer units derived from an unsaturated ester other than unsaturated carboxylic glycidyl esters.

Examples of the unsaturated ester for the monomer units derived from an unsaturated ester include vinyl acetate, vinyl propionate, methyl acrylate, ethyl acrylate, butyl acrylate, methyl methacrylate, and ethyl methacrylate.

When the resin (B4) further has monomer units derived from an unsaturated ester, the content of the monomer units derived from ethylene in the resin (B4) is, from the viewpoint of the transparency of an encapsulant sheet for a solar cell, preferably not less than 60% by mass, more preferably not less than 65% by mass, and from the viewpoint of the transparency of an encapsulant sheet for a solar cell, it is preferably not more than 98% by mass, more preferably not more than 90% by mass, even more preferably not more than 80% by mass, still even more preferably not more than 75% by mass.

From the viewpoint of the transparency of an encapsulant sheet for a solar cell, the sum total of the content of the monomer units derived from the unsaturated carboxylic glycidyl ester and the content of the monomer units derived from the unsaturated ester in the resin (B4) is preferably not less than 2% by mass, more preferably not less than 10% by mass, even more preferably not less than 20% by mass, still even more preferably not less than 25% by mass, and from the viewpoint of the transparency of an encapsulant sheet for a solar cell, it is preferably not more than 40% by mass, more preferably not more than 35% by mass. It is noted that the sum total of said content of the monomer units derived from ethylene and said content of the monomer units derived from the unsaturated carboxylic glycidyl ester and said content of the monomer units derived from the unsaturated ester is taken as 100% by mass.

Examples of the resin (B4) include an ethylene-glycidyl acrylate copolymer, an ethylene-glycidyl methacrylate copolymer, an ethylene-vinyl acetate-glycidyl acrylate copolymer, an ethylene-vinyl acetate-glycidyl methacrylate copolymer, an ethylene-acrylic ester-glycidyl acrylate copolymer, and an ethylene-acrylic ester-glycidyl methacrylate copolymer.

Examples of methods for producing the resin (B3) and resin (B4) include a high-pressure polymerization method, a slurry polymerization method, a solution polymerization method, a bulk polymerization method, and a gas phase polymerization method.

### [Content of Ethylene-Unsaturated Ester Copolymer (A) and Content of Olefin Resin (B)]

The content of the ethylene-unsaturated ester copolymer (A) according to the present invention is not less than 91% by mass but less than 99% by mass, and from the viewpoints of the storage stability, transparency, and durability of adhesion to glass of an encapsulant sheet for a solar cell, it is preferably not less than 94% by mass, more preferably not less than 95% by mass, and preferably is not more than 98.5% by mass, more preferably not more than 98% by mass. The content of the olefin resin (B) according to the present invention is more than 1% by mass but not more than 9% by mass, and from the viewpoint of the transparency of an encapsulant sheet for a solar cell, it is preferably not less than 1.5% by mass, more preferably not less than 2% by mass, and preferably is not more than 6% by mass, more preferably not more than 5% by mass. It is noted that the sum total of the content of the ethylene-unsaturated ester copolymer (A) and the content of the olefin resin (B) is taken as 100% by mass.

### [Silicon Dioxide]

The silicon dioxide to be used for the present invention is a compound represented by a formula SiO₂, and examples thereof include crystalline silicon dioxide and amorphous silicon dioxide. Examples of the amorphous silicon dioxide include calcined amorphous silicon dioxide and non-calcined amorphous silicon dioxide.

Examples of the crystalline silicon dioxide include CRYSTALITE produced by Tatsumori Ltd. Examples of the calcined amorphous silicon dioxide include a calcined silica CARPLEX CS-5 produced by Evonik Degussa Japan Co., Ltd. Examples of the non-calcined amorphous silicon dioxide include VK-SP 30S produced by Xuan Cheng Jing Rui New Material Co., Ltd., China, porous silica produced by Suzuki Yushi Industrial Co., Ltd., Gasil AB905 produced by PQ Corporation, Snow Mark SP-5 produced by MARUKAMA Co., Ltd., silica CARPLEX #80, CARPLEX EPS-2, and CARPLEX FPS-101 produced by Evonik Degussa Japan Co., Ltd.

As the silicon dioxide, a single product may be used or alternatively two or more products may be used in combination. When two or more types of silicon dioxide are used together, it is preferred to use non-calcined amorphous silicon dioxide and calcined amorphous silicon dioxide in combination.

Ignition loss of silicon dioxide is preferably not less than 1.3%, more preferably not less than 1.5%, even more preferably not less than 2%, still even more preferably not less than 3%. The ignition loss of silicon dioxide is usually not more than 15%, preferably not more than 13%, more preferably not more than 10%. The ignition loss is a value measured in accordance with the method defined in JIS K1150-1994 using a sample dried at about 150° C. under vacuum.

The average particle diameter of the silicon dioxide is preferably not less than 0.001 μm, more preferably not less than 0.01 μm, and is preferably not more than 30 μm, more preferably not more than 10 μm, from the viewpoint of enabling the silicon dioxide to disperse more uniformly in the encapsulant sheet for a solar cell.

The average particle diameter of silicon dioxide is a median particle diameter of the particle size distribution measured by volume from a diffraction image formed on a focal plane by applying laser beams to a dispersion liquid of the silicon dioxide dispersed in ethanol and then collecting the scattered light with a lens.

Examples of the method for adjusting the average particle diameter of silicon dioxide to 0.001 μm to 30 μm include a method of crushing the silicon dioxide with a mortar and a method of pulverizing the silicon dioxide with a jet mill.

The content of the silicon dioxide in the encapsulant sheet for a solar cell of the present invention is 0.001 parts by mass to 5 parts by mass relative to 100 parts by mass in total of the content of the ethylene-unsaturated ester copolymer (A) and the content of the olefin resin (B). From the viewpoint of enhancing the insulating property of an encapsulant sheet for a solar cell, the content of the silicon dioxide is preferably not less than 0.01 parts by mass, more preferably not less than 0.1 parts by mass, and preferably is not more than 5 parts by mass, more preferably not more than 0.5 parts by mass.

### [Silane Coupling Agent]

The silane coupling agent to be used for the present invention is added in order to enhance the adhesion of the encapsulant sheet to a light-receiving-surface protective member, a lower protective member (backsheet), and a solar cell element. Examples of the silane coupling agent include γ-chloropropyltrimethoxysilane, vinyltrichlorosilane, vinyltriethoxysilane, vinyl-tris(β-methoxyethoxy)silane, γ-methacryloxypropyltrimethoxysilane, β-(3,4-ethoxycyclohexyl)ethyl-trimethoxysilane, γ-glycidoxypropyltrimethoxysilane, vinyltriacetoxysilane, γ-mercaptopropyltrimethoxysilane, γ-aminopropyltrimethoxysilane, N-β-(aminoethyl)-γ-aminopropyltrimethoxysilane, allyltrimethoxysilane, allyltriethoxysilane, allyltriisopropoxysilane, vinylethyltrimethoxysilane, vinylethyltriethoxysilane, vinylpropyltrimethoxysilane, vinylbutyltrimethoxysilane, vinylbutyltriethoxysilane, vinylbutyltriisopropoxysilane, vinylpentyltrimethoxysilane, vinylhexyltrimethoxysilane, vinylheptyltrimethoxysilane, and vinyloctyltrimethoxysilane. Regarding these silane coupling agents, a single agent may be used, or alternatively two or more agents may be used in combination.

As a silane coupling agent, γ-methacryloxypropyltrimethoxysilane,allyltrimethoxysilane, allyltriethoxysilane, allyltriisopropoxysilane, vinylethyltrimethoxysilane, vinylethyltriethoxysilane, vinylpropyltrimethoxysilane, vinylbutyltrimethoxysilane, vinylbutyltriethoxysilane, or vinylbutyltriisopropoxysilane is preferable, and vinylbutyltrimethoxysilane is more preferable.

The content of the silane coupling agent according to the present invention is 0.001 parts by mass to 0.5 parts by mass relative to 100 parts by mass in total of the content of the ethylene-unsaturated ester copolymer (A) and the content of the olefin resin (B). The content of the silane coupling agent is preferably not less than 0.05 parts by mass, more preferably not less than 0.1 parts by mass, and is preferably not more than 0.3 parts by mass, more preferably not more than 0.2 parts by mass, and even more preferably not more than 0.15 parts by mass.

### [Encapsulant Sheet for a Solar Cell]

The encapsulant sheet for a solar cell according to the present invention is a sheet comprising an ethylene-unsaturated ester copolymer (A), an olefin resin (B), silicon dioxide, and a silane coupling agent. The encapsulant sheet of the present invention is made of a composition comprising an ethylene-unsaturated ester copolymer (A), an olefin resin (B), silicon dioxide, and a silane coupling agent. The “encapsulant sheet for a solar cell” is a sheet for bonding or fixing members of a solar cell together. It is noted that, in the following description, an “encapsulant sheet for a solar cell” may be referred simply as an “encapsulant sheet.”

The encapsulant sheet for a solar cell according to the present invention is higher in volume resistivity as compared with conventional encapsulant sheet based on ethylene-vinyl acetate copolymers. Therefore, the encapsulant sheet of the present invention is used suitably as a solar cell encapsulant for encapsulating and protecting a solar cell element. Conventional solar cells sometimes deteriorate in power generation performance due to insulation failure of encapsulant sheets when they are used under high voltage. Since the encapsulant sheet of the present invention is excellent in insulating property, it can inhibit deterioration in power generation performance.

A method for producing the encapsulant sheet of the present invention may be a method of processing a composition comprising an ethylene-unsaturated ester copolymer (A), an olefin resin (B), silicon dioxide, and a silane coupling agent into a sheet by using a sheet processing machine such as a T-die extruder and a calendering machine.

In an acceptable embodiment, an ethylene-unsaturated ester copolymer (A), an olefin resin (B), silicon dioxide, and a silane coupling agent are melt-kneaded in advance to form a resin composition and then the resin composition is fed to a sheet processing machine and processed into a sheet. In another acceptable embodiment, resin pellets prepared by attaching silicon dioxide to a surface of pellets comprising an ethylene-unsaturated ester copolymer (A) and an olefin resin (B) and a silane coupling agent are fed to a sheet processing machine.

The encapsulant sheet according to the present invention may, according to necessity, comprise additives, such as a crosslinking agent, a crosslinking aid, a UV absorber, an antioxidant, a light stabilizer, an antifogging agent, a plasticizer, asurfactant, acoloringagent,anantistaticagent, a discoloration inhibitor, a flame retardant, a crystallization nucleator, and a lubricant. Regarding such additives, a single agent may be used, or alternatively two or more agents may be used in combination.

Examples of the crosslinking agent includes those that generate radicals at temperatures higher than the melting points of the ethylene-unsaturated ester copolymer (A) and the olefin resin (B) according to the present invention, and preferred is an organic peroxide the one-hour half-life temperature of which is higher than the melting points of the ethylene-unsaturated ester copolymer (A) and the olefin resin (B) contained in the encapsulant sheet. In order to allow a crosslinking agent, which is unlikely to decompose during sheet processing, to be decomposed by heating during the assembly of a solar cell and thereby render crosslinking of the ethylene-unsaturated ester copolymer (A) and the olefin resin (B) contained in the encapsulant sheet easier to proceed, the crosslinking agent is more preferably an organic peroxide the one-hour half-life temperature of which is 70° C. to 135° C. Moreover, an organic peroxide having a one-hour half-life temperature of not lower than 100° C. is more preferable from the viewpoint of the decomposition resistance of a crosslinking agent at the time of sheet processing; examples of a preferable organic peroxide include tert-butylperoxy-2-ethylhexyl carbonate, 2,5-dimethylhexane-2,5-dihydroperoxide, 2,5-dimethyl-2,5-di(tert-butylperoxy)hexane-3, di-tert-butyl peroxide, tert-dicumyl peroxide, 2, 5-dimethyl-2,5-di(tert-butylperoxy)hexane, dicumyl peroxide, α,α′ -bis(tert-butylperoxyisopropyl)benzene, n-butyl-4,4-bis(tert-butylperoxy)butane, 2,2-bis(tert-butylperoxy)butane, 1,1-bis(tert-butylperoxy)cyclohexane, 1,1-bis(tert-butylperoxy)-3,3,5-trimethylcyclohexane, tert-butyl peroxybenzoate, and benzoyl peroxide. As the organic peroxide, 1,1-bis(tert-butylperoxy)-3,3,5-trimethylcyclohexane or tert-butylperoxy-2-ethylhexyl carbonate is preferred in order to inhibit deterioration in the insulating property of an encapsulant sheet. The content of the crosslinking agent contained in the encapsulant sheet according to the present invention is preferably, for example, 0.001 parts by mass to 0.5 parts by mass relative to 100 parts by mass in total of the content of the ethylene-unsaturated ester copolymer (A) and the content of the olefin resin (B).

When an encapsulant sheet contains a crosslinking agent, a crosslinking agent remaining undecomposed after being heated during the assembly of a solar cell may be decomposed slowly during use of the solar cell to cause degradation of the encapsulant sheet, such as discoloration. In order to prevent such degradation of an encapsulant sheet caused by a remaining crosslinking agent, a smaller content of a crosslinking agent contained in an encapsulant sheet is preferred. From the perspective of being able to provide the encapsulant sheet according to the present invention with a crosslinked structure with a high gel fraction even with a small amount of crosslinking agent, the encapsulant sheet preferably contains a crosslinking aid, described below, in combination with the crosslinking agent. Examples of the crosslinking aid include a monofunctional crosslinking aid, a bifunctional crosslinking aid, a trifunctional crosslinking aid, and hexafunctional crosslinking aid. Examples of the monofunctional crosslinking aid include acrylates and methacrylates. Examples of the bifunctional crosslinking aid include N,N′-m-phenylenebismaleimide. Examples of the trifunctional crosslinking aid include triallyl isocyanurate and trimethylolpropane triacrylate. Examples of the hexafunctional crosslinking aid include dipentaerythritol hexaacrylate. From the perspective of maintaining adhesion of the encapsulant sheet to glass for a long time, the content of the crosslinking aid contained in the encapsulant sheet according to the present invention is preferably, for example, not less than 0.1 parts by mass and is preferably not more than 10 parts by mass, more preferably not more than 5 parts by mass, relative to 100 parts by mass in total of the content of the ethylene-unsaturated ester copolymer (A) and the content of the olefin resin (B).

Examples of the UV absorber include a benzophenone-based UV absorber, a benzotriazole-based UV absorber, a hindered amine UV absorber, a triazine-based UV absorber, a salicylic acid-based UV absorber, and a cyanoacrylate-based UV absorber. Regarding the UV absorber, a single agent may be used or alternatively two or more agents may be used in combination.

Examples of the benzophenone-based UV absorber include 2-hydroxy-4-octoxybenzophenone and 2-hydroxy-4-methoxy 5-sulfobenzophenone.

Examples of the benzotriazole-based UV absorber include 2-(2′-hydroxy-5-methylphenyl)benzotriazole, 2-(2H-1,2,3-benzotriazol-2-yl)-4,6-di-tert-butylphenol; 2-(5-chloro-2H-1,2,3-benzotriazol-2-yl)-4,6-di-tert-butylph enol; 2-(2H-1,2,3-benzotriazol-2-yl)-4,6-di-tert-pentyl phenol; 2-(5-chloro-2H-1,2,3-benzotriazol-2-yl)-4,6-di-tert-pentylphenol; 2-(2H-1,2,3-benzotriazol-2-yl)-4-tert-butylphenol; 2-(5-chloro-2H-1,2,3-benzotriazol-2-yl)-4-tert-butylphenol; 2-(2H-1,2,3-benzotriazol-2-yl)-4-methylphenol; 2-(5-chloro-2H-1,2,3-benzotriazol-2-yl)-4-methylphenol; 2-(2H-1,2,3-benzotriazol-2-yl)-6-dodecyl-4-methylphenol; 2-(5-chloro-2H-1,2,3-benzotriazol-2-yl)-6-dodecyl-4-methylphenol;

2-(2H-1,2,3-benzotriazol-2-yl)-4-methyl-6-tert-butylphenol; and 2-(5-chloro-2H-1,2,3-benzotriazol-2-yl)-4-methyl-6-tert-butylphenol.

When a benzophenone-based UV absorber and a benzotriazole-based UV absorber are used in combination as a UV absorber, the sum total of the contents of the benzophenone-based UV absorber and the benzotriazole-based UV absorber is preferably not less than 0.01 parts by mass, more preferably not less than 0.1 parts by mass, and is preferably not more than 5 parts by mass, more preferably not more than 1.0 parts by mass, relative to 100 parts by mass in total of the content of the ethylene-unsaturated ester copolymer (A) and the content of the olefin resin (B).

When a benzotriazole-based UV absorber and an organic peroxide are used in combination, the mass ratio (I:II) of the benzotriazole-based UV absorber (I) to the organic peroxide (II) is preferably not less than 90:10, more preferably not less than 80:20, and is preferably not more than 10:90, more preferably not more than 20:80.

Examples of the hindered amine UV absorber include phenyl salicylate and p-tert-buthylphenyl salicylate. The content of the hindered amine UV absorber is preferably 0.01 parts by mass to 5 parts by mass relative to 100 parts by mass in total of the content of the ethylene-unsaturated ester copolymer (A) and the content of the olefin resin (B).

Examples of the triazine-based UV absorbers include 2-(2-hydroxy-4-hydroxymethylphenyl)-4,6-diphenyl-s-triazine, 2-(2-hydroxy-4-hydroxymethylphenyl)-4,6-bis(2,4-dimethylphenyl)-s-triazine, 2-[2-hydroxy-4-(2-hydroxyethyl)phenyl]-4,6-diphenyl-s-triazine, 2-[2-hydroxy-4-(2-hydroxyethyl)phenyl]-4,6-bis(2,4-dimethylphenyl)-s-triazine, 2-[2-hydroxy-4-(2-hydroxyethoxy)phenyl]-4,6-diphenyl-s-triazine, 2-[2-hydroxy-4-(2-hydroxyethoxy)phenyl]-4,6-bis(2,4-dimethylphenyl)-s-triazine, 2-[2-hydroxy-4-(3-hydroxypropyl)phenyl]-4,6-diphenyl-s-triazine, 2-[2-hydroxy-4-(3-hydroxypropyl)phenyl]-4,6-bis(2,4-dimethylphenyl)-s-triazine, 2-[2-hydroxy-4-(3-hydroxypropoxy)phenyl]-4,6-diphenyl-s-triazine, 2-[2-hydroxy-4-(3-hydroxypropoxy)phenyl]-4,6-bis(2,4-dimethylphenyl)-s-triazine, 2-[2-hydroxy-4-(4-hydroxybutyl)phenyl]-4,6-diphenyl-s-triazine, 2-[2-hydroxy-4-(4-hydroxybutyl)phenyl]-4,6-bis(2,4-dimethylphenyl)-s-triazine, 2-[2-hydroxy-4-(4-hydroxybutoxy)phenyl]-4,6-diphenyl-s-triazine, 2-[2-hydroxy-4-(4-hydroxybutoxy)phenyl]-4,6-bis(2,4-dimethylphenyl)-s-triazine, 2-(2-hydroxy-4-hydroxymethylphenyl)-4,6-bis(2-hydroxy-4-methylphenyl)-s-triazine, 2-[2-hydroxy-4-(2-hydroxyethyl)phenyl]-4,6-bis(2-hydroxy-4-methylphenyl)-s-triazine, 2-[2-hydroxy-4-(2-hydroxyethoxy)phenyl]-4,6-bis(2-hydroxy-4-methylphenyl)-s-triazine, 2-[2-hydroxy-4-(3-hydroxypropyl)phenyl]-4,6-bis(2-hydroxy-4-methylphenyl)-s-triazine, 2-[2-hydroxy-4-(3-hydroxypropoxy)phenyl]-4,6-bis(2-hydroxy-4-methylphenyl)-s-triazine, 2-[4,6-bis(2,4-dimethylphenyl)-1,3,5-triazin-2-yl]-5-(octyloxy)phenol, and 2-(4,6-diphenyl-1,3,5-triazin-2-yl)-5-hexyloxy-phenol.

Examples of the salicylic acid-based UV absorber include phenyl salicylate and 4-tert-butylphenyl salicylate.

Examples of the cyanoacrylate-based UV absorber include 2-ethylhexyl-2-cyano-3,3′-diphenyl acrylate and ethyl-2-cyano-3,3′-diphenyl acrylate.

Examples of the antioxidant include an amine-based antioxidant, a phenol-based antioxidant, a phosphorus-containing antioxidant, a bisphenyl antioxidant, and a hindered amine antioxidant, and specifically include di-tert-butyl-p-cresol, aryl phosphites, such as bis(2,2,6.6-tetramethyl-4-piperazyl) sebacate tris(2,4-di-tert-butylphenyl) phosphite, tris(nonylphenyl) phosphite, or triphenyl phosphite, alkyl phosphites, such as trisisodecyl phosphite, trilauryl phosphite, and tris(tridecyl) phosphite, alkylaryl phosphites, such as diphenylisooctyl phosphite, diphenylisodecyl phosphite, diisodecylphenyl phosphite, diisooctyloctylphenyl phosphite, phenylneopentylglycol phosphite, 2,4,6-tri-tert-buthylphenyl(2-butyl-2-ethyl-1,3-propanediol)phosphite, and (2,4,8,10-tetrakis(tert-butyl)-6-{(ethylhexyl)oxy}-12H-dibenzo)[d,g]1,3,2-dioxaphosphocin, octadecyl-3-(3,5-di-tert-butyl-4-hydroxyphenyl)propionate, pentaerythritol-tetrakis[3-(3,5-di-tert-butyl-4-hydroxyphenyl)propionate], 1,3,5-trimethyl-2,4,6-tris(3,5-di-tert-butyl-4-hydroxybenzyl)benzene, thiodiethylene-bis[3-(3,5-di-tert-butyl-4-hydroxyphenyl)propionate], N,N′-hexane-1,6-diylbis[3-(3,5-di-tert-butyl-4-hydroxyphenyl)propionamide], diethyl((3,5-bis(1,1-dimethylethyl)-4-hydroxyphenyl)methyl)phosphate, 3,3′,3″,5,5′,5″-hexa-tert-butyl-α,α′,α″-(mesitylene-2,4,6-triyl)tri-p-cresol, ethylenebis(oxyethylene)bis(3-(5-tert-butyl-4-hydroxy-m-tolyl)propionate), hexamethylenebis(3-(3,5-di-tert-butyl-4-hydroxyphenyl)propionate), 1,3,5-tris(3,5-di-tert-butyl-4-hydroxybenzyl)-1,3,5-triazine-2,4,6(1H,3H,5H)-trione, 1,3,5-tris((4-tert-butyl-3-hydroxy-2,6-xylyl)methyl)-1,3,5-triazine-2,4,6(1H,3H,5H)-trione, 2,6-di-tert-butyl 4-(4,6-bis(octylthio)-1,3,5-triazin-2-ylamino)phenol, and 3,9-bis(2-(3-(3-tert-butyl-4-hydroxy-5-methylphenyl)propionyloxy)-1,1-dimethylethyl)-2,4,8,10-tetraoxaspiro(5.5)undecane.

The content of the antioxidant is preferably not less than 0.02 part by mass, more preferably not less than 0.05 parts by mass, and is preferably not more than 0.5 parts by mass, more preferably not more than 0.3 parts by mass, relative to 100 parts by mass in total of the content of the ethylene-unsaturated ester copolymer (A) and the content of the olefin resin (B).

Examples of the coloring agent include white coloring agents such as titanium white and calcium carbonate, blue coloring agents such as ultramarine, black coloring agents such as carbon black, and milk white coloring agents such as glass beads and a light-diffusing agent; titanium white is preferable. The content of such a coloring agent is preferably not less than 1 part by mass, and is preferably not more than 10 parts by mass, more preferably not more than 5 parts by mass, relative to 100 parts by mass in total of the content of the ethylene-unsaturated ester copolymer (A) and the content of the olefin resin (B).

Examples of the plasticizer include esters of polybasic acids and esters of polyhydric alcohols. Specific examples thereof include dioctyl phthalate, dihexyl adipate, triethylene glycol di-2-ethylbutyrate, butyl sebacate, tetraethylene glycol diheptanoate, and triethylene glycol dipelargonate.

The content of the plasticizer is preferably not more than 5 parts by mass relative to 100 parts by mass in total of the content of the ethylene-unsaturated ester copolymer (A) and the content of the olefin resin (B).

Examples of the discoloration inhibitor include a salt of a higher fatty acid with a metal, such as cadmium and barium. Examples of the salt of a metal with a higher fatty acid include a metallic soap. The content of the discoloration inhibitor is preferably not more than 5 parts by mass relative to 100 parts by mass in total of the content of the ethylene-unsaturated ester copolymer (A) and the content of the olefin resin (B).

Examples of the flame retardant include an organic flame retardant containing one or more halogen atoms in its molecule and an inorganic flame retardant containing one or more halogen atoms in its molecule. A chlorine atom or a bromine atom is preferable as the halogen atom.

Examples of the organic flame retardant containing one or more halogen atoms in its molecule include tris(2,3-dibromopropyl) isocyanurate or the like and their polymers, chlorinated paraffin, chlorinated polyethylene, hexachloroendomethylenetetrahydrophthalic acid, perchloropentacyclodecane, tetrachlorophthalic anhydride, 1,1,2,2-tetrabromoethane, 1,4-dibromobutane, 1,3-dibromobutane,1,5-dibromopentane,ethyla-bromobutyrate, and 1,2,5,6,9,10-hexabromocyclodecane.

Examples of the inorganic flame retardant containing one or more halogen atoms in its molecule include hydroxides such as aluminum hydroxide and magnesium hydroxide, phosphates such as ammonium phosphate and zinc phosphate, and red phosphorus.

The content of the flame retardant is preferably not less than 1 part by mass, and is preferably not more than 70 parts by mass, more preferably not more than 50 parts by mass, relative to 100 parts by mass in total of the content of the ethylene-unsaturated ester copolymer (A) and the content of the olefin resin (B).

The encapsulant sheet according to the present invention may further comprise antimony trioxide or expanded graphite as a flame retardant aid. When expanded graphite is contained as a flame retardant aid, the content of the expanded graphite is preferably not less than 1 part by mass, and is preferably not more than 25 parts by mass, more preferably not more than 17 parts by mass, relative to 100 parts by mass in total of the content of the ethylene-unsaturated ester copolymer (A) and the content of the olefin resin (B). When antimony trioxide is contained as a flame retardant aid, the content of the antimony trioxide is preferably not less than 2 parts by mass, and is preferably not more than 10 parts by mass, more preferably not more than 9 parts by mass, relative to 100 parts by mass in total of the content of the ethylene-unsaturated ester copolymer (A) and the content of the olefin resin (B).

Examples of the lubricant include a fatty acid amide compound and a phosphite compound. Specific examples of the fatty acid amide compound include oleamide, erucamide, stearamide, behenamide, ethylenebisoleamide, and ethylene bisstearamide. Examples of the phosphite compound include alkyl phosphites, such as decyl phosphite; alkyl acid phosphates, such as decyl acid phosphate; aryl acid phosphates, such as phenyl acid phosphate; trialkylphosphates, suchastrihexylphosphate; triaryl phosphates, such as tricresyl phosphate; and zinc dithiophosphate.

The content of the lubricant is preferably not less than 0.05 parts by mass, and is preferably not more than 1 part by mass, more preferably not more than 0.5 parts by mass, relative to 100 parts by mass in total of the content of the ethylene-unsaturated ester copolymer (A) and the content of the olefin resin (B).

Examples of the light stabilizer include a hindered amine compound. Examples of the hindered amine compound include tetrakis(1,2,2,6,6-pentamethyl-4-piperidyl) 1,2,3,4-butanetetracarboxylate, tetrakis(1,2,2,6,6-pentamethyl-4-piperidyl)-1,2,3,4-butane tetracarboxylate, 1,2,2,6,6-pentamethyl-4-piperidyl-1,2,3,4-butane tetracarboxylate, tridecyl-1,2,3,4-butane tetracarboxylate, methyl-1,2,2,6,6-pentamethyl-4-piperidyl sebacate, (bis(1,2,2,6,6-pentamethyl-4-piperidyl)[[3,5-bis(1,1-dimethylethyl)-4-hydroxyphenyl]methyl]butyl malonate, 4-piperidinol(2,2,6,6-tetramethyl)-4-benzoate, poly[[6-(1,1,3,3-tetrametylbutyl)amino-1,3,5-triazine-2,4-diyl][(2,2,6,6-tetramethyl-4-piperidyl)imino]hexamethylene[(2,2,6,6-tetramethyl-4-piperidyl)imino]], a polycondensate of dimethyl succinate-1-(2-hydroxyethyl)-4-hydroxy-2,2,6,6-tetramethylpiperidine, 1,1-(1,2-ethane-diyl)bis(3,3,5,5-tetramethyl piperazinone, bis(2,2,6,6-tetramethyl-4-piperidyl)sebacate, a condensate of 2,2,6,6-tetramethylpiperidinol, tridecyl alcohol, and 1,2,3,4-butanetetracarboxylic acid, a condensate of 1,2,3,4-butanetetracarboxylic acid, 2,2,6,6-tetramethyl-4-piperidinol, and β,β,β,β-tetramethyl-3,9-(2,4,8,10-tetraoxaspiro[5.5]undecane)-diethanol, a mixture of a condensate of 1,2,3,4-butanetetracarboxylic acid and 1,2,2,6,6-pentamethyl-4-piperidinol and 3,9-bis(2-hydroxy-1,1-dimethylethyl)-2,4,8,10-tetraoxaspiro[5.5]undecane.

Exemplary commercial products include LA-52, LA-57, LA-62, LA-63, and LA-63P, LA-67, and LA-68 (all produced by ADEKA), Tinuvin (registered trademark) 144, Tinuvin 622LD, Tinuvin 744, Tinuvin 765, Tinuvin 770, and CHIMASSORB (registered trademark) 944LD (all produced by Ciba Specialty Chemicals Corporation), UV-3034 (produced by B. F. Goodrich), Sanol (registered trademark) LS770 (produced by Sankyo), and Tinuvin 770 DF (produced by BASF). Regarding the light stabilizer, a single agent may be used or alternatively two or more agents may be used in combination.

### [Solar Cell]

The solar cell of the present invention is composed of a light-receiving-surface protective member, a solar cell element, a lower protective member, and an encapsulant sheet, and generally, a light-receiving-surface protective member, an encapsulant sheet, a solar cell element, another encapsulant sheet, and a lower protective member are laminated in order. Examples of the light-receiving-surface protective member in the solar cell include a transmissive protective member such as glass and plastics. Examples of the lower protective member include protective members such as plastics, ceramics, stainless steel, and aluminum.

The solar cell is assembled in the following manner, for example.

On each side of a planar solar cell element such as a silicon substrate for a solar cell, one sheet of the encapsulant sheet of the present invention is disposed. The above-mentioned light-receiving-surface protective member is brought into contact with an exposed surface of one of the encapsulant sheets and the above-mentioned lower protective member is brought into contact with an exposed surface of the other encapsulant sheet. Subsequently, the set is put into a vacuum laminator and the inside of the vacuum laminator is brought into a vacuum state, and then it is heated to a temperature at which the encapsulant sheet melts. After allowing the encapsulant sheets to melt to some extent, the inside of the vacuum laminator is transferred from the vacuum state to a pressurized state under heating, and then pressurization is carried out under heating. By the heating under vacuum and the heating under pressure, the polymer contained in the encapsulant sheet disposed on one side of the solar cell element and the polymer contained in the encapsulant sheet disposed on the other side of the solar cell element are each crosslinked. Moreover, as a result of the heatings, the silane coupling agent contained in one encapsulant sheet is reacted with the light-receiving-surface protective member, the silane coupling agent contained in the other encapsulant sheet is reacted with the lower protective member, and the silane coupling agents contained in both the encapsulant sheet are reacted with the solar cell element. Therefore, one of the encapsulant sheet is bonded to the light-receiving-surface protective member, the other encapsulant sheet is bonded to the lower protective member, and both the encapsulant sheets are bonded to the solar cell element.

Examples of the solar cell element include single crystal silicon, polycrystalline silicon, amorphous silicon, and compound type elements, such as Groups III-V compound semiconductors and Groups II-VI compound semiconductors, including gallium-arsenide, copper-indium-selenium, and cadmium-tellurium.

### EXAMPLES

The present invention is described in more detail below by Examples.

[Content of Monomer Units Derived from Vinyl Acetate Contained in an Ethylene-Vinyl Acetate Copolymer]

The content of monomer units derived from vinyl acetate in an ethylene-vinyl acetate copolymer was measured in accordance with JIS K7192, where the sum total of the content of monomer units derived from vinyl acetate and the content of monomer units derived from ethylene was taken as 100% by mass.

[Contents of Monomer Units Derived from Vinyl Acetate and Monomer Units Derived from Glycidyl Methacrylate Contained in an Ethylene-Vinyl Acetate-Glycidyl Methacrylate Copolymer]

A 0.3 mm thick pressed sheet was prepared and then subjected to IR measurement. For vinyl acetate, the absorbance of the characteristic absorption of a methyl group of an acetate appearing near 620 cm⁻¹ in the measured infrared absorption spectrum, and for glycidyl methacrylate, the absorbance of the characteristic absorption of a glycidyl group appearing near 900 cm⁻¹ were corrected with the thickness of the pressed sheet, and then the content of monomer units derived from vinyl acetate and the content of monomer units derived from glycidyl methacrylate were determined by a calibration curve method, where the contents of the monomer units are based on 100% by mass in total of the content of the monomer units derived from ethylene, the content of the monomer units derived from vinyl acetate, and the content of the monomer units derived from glycidyl methacrylate.

[Contents of Monomer Units Derived from Methyl Acrylate and Monomer Units Derived from Glycidyl Methacrylate Contained in an Ethylene-Methyl Acrylate-Glycidyl Methacrylate Copolymer]

A 0.3 mm thick pressed sheet was prepared and then subjected to IR measurement. For methyl acrylate, the absorbance of the characteristic absorption of a carbonyl group (C═O) appearing near 1700 cm⁻¹ in the measured infrared absorption spectrum, and for glycidyl methacrylate, the absorbance of the characteristic absorption of a glycidyl group appearing near 900 cm⁻¹ were corrected with the thickness of the pressed sheet. The content of monomer units derived from methyl acrylate and the content of monomer units derived from glycidyl methacrylate were determined by a calibration curve method, where the contents of the monomer units are based on 100% by mass in total of the content of the monomer units derived from ethylene, the content of the monomer units derived frommethyl acrylate, and the content of the monomer units derived from glycidyl methacrylate.

[Content of Monomer Units Derived from Methacrylic Acid Contained in an Ethylene-Methacrylic Acid Copolymer]

A 0.3 mm thick pressed sheet was prepared and then subjected to IR measurement. The absorbance of the characteristic absorption of a carbonyl group (C═O) appearing near 1700 cm⁻¹ in the measured infrared absorption spectrum was corrected with the thickness of the pressed sheet, and then the content of monomer units derived from methacrylic acid was determined by a calibration curve method, where the contents of the monomer units are based on 100% by mass in total of the content of the monomer units derived from ethylene and the content of the monomer units derived from methacrylic acid.

[Content of Monomer Units Derived from Methyl Methacrylate Contained in an Ethylene-Methyl Methacrylate Copolymer]

A 0.3 mm thick pressed sheet was prepared and then subjected to IR measurement. The absorbance of the characteristic absorption of a carbonyl group (C═O) appearing near 1700 cm⁻¹ in the measured infrared absorption spectrum was corrected with the thickness of the pressed sheet, and then the content of monomer units derived from methyl methacrylate was determined by a calibration curve method, where the contents of the monomer units are based on 100% by mass in total of the content of the monomer units derived from ethylene and the content of the monomer units derived from methyl methacrylate.

[Average Particle Diameter (unit: μm)]

The average particle diameter of silicon dioxide was calculated by the following method.

Silicon dioxide was added to ethanol and was dispersed with a homogenizer for 10 minutes. The dispersion liquid was irradiated with laser beams and the scattering light was collected with a lens. The diffraction pattern formed on the focal plane was measured as a particle size distribution on volume basis by means of a Microtrac particle size analyzer (MT-3000EX II manufactured by Nikkiso Co., Ltd.) and a median particle diameter of the particle size distribution was determined.

### [Ignition Loss (Unit: %)]

The ignition loss of silicon dioxide was measured in accordance with the method defined in JIS K1150-1994 using a sample dried at about 150° C. for 2 hours under vacuum.

[Melt Flow Rate (MFR, Unit: g/10 min)]

The melt flow rate of a resin was measured under conditions including a temperature of 190° C. and a load of 21.18 N in accordance with the method specified in JIS K7210-1995.

[Volume Resistivity (Unit: Ω·cm)]

A sheet was placed on a large diameter electrode for a plate sample (SME-8310, manufactured by DKK-TOA CORPORATION), a voltage of 500 V was applied to it for 1 minute and the resistance thereof was measured with a digital insulation resistance tester (DSM-8103, manufactured by DKK-TOA CORPORATION). The volume resistivity was calculated on the basis of the resistance.

### [Light Transmittance (Unit: %)]

Each of the copolymers of Examples and Comparative Examples was molded into a sheet with a thickness of about 500 μm by pressing the copolymer under a pressure of 2 MPa with a 100° C. hot presser, and then cooling it for 5 minutes with a 30° C. cooling presser. A light transmission spectrum along the thickness direction of the sheet was measured with a spectrophotometer (UV-3150 manufactured by Shimadzu Corporation). An average value of the light transmittance within the wavelength range from 400 nm to 1200 nm was calculated. A larger average of light transmittance indicates better transparency.

[Adhesion Strength to Glass (Unit: N/10 mm]

A glass plate for a solar cell (white glass sized 65 mm×65 mm, 3.2 mm in thickness, produced by AGC fabritech Co. , Ltd.), a pressed sheet with a thickness of about 500 μm, and a backsheet (Tedlar/PET/Tedlar, 320 μm in thickness) were layered in order. Following degassing at 150° C. for 5 minutes by means of a vacuum laminator, the layers were vacuum laminated for 25 minutes, preparing a sample for measurement of adhesion strength to glass. The pressed sheet and the backsheet laminated were cut in a width of 10 mm, and then peel strength at the interface between the glass and the pressed sheet was measured with a tensile tester (STA-1225, manufactured by ORIENTEC Co., Ltd.) under an atmosphere at 23° C. and 50% RH. The pulling rate was adjusted to 100 mm/min and the peel angle was adjusted to 180 degrees. The peel strength measured when the peel strength had reached a steady state was taken as an adhesion strength to glass.

The adhesion strength to glass after a wet heat test was measured by the above-described method after storing the sample for 1000 hours in a thermostatic chamber preset to 85° C. and 85% RH.

[Sheet Storage Stability (Adhesion Strength to Glass (Unit: N/10 mm))]

After storing a pressed sheet with a thickness of about 500 μm for 3 hours in a thermostatic chamber preset to 85° C. and 85% RH, a glass plate for a solar cell (white glass sized 65 mm×65 mm, 3.2 mm in thickness, produced by AGC fabritech Co., Ltd.), the pressed sheet with a thickness of about 500 μm, and a backsheet (Tedlar/PET/Tedlar, 320 μm in thickness) were layered in order. Following degassing at 150° C. for 5 minutes by means of a vacuum laminator, the layers were vacuum laminated for 25 minutes, preparing a sample for measurement of adhesion strength to glass. The pressed sheet and the backsheet laminated were cut in a width of 10 mm, and then peel strength at the interface between the glass and the pressed sheet was measured with a tensile tester (STA-1225, manufactured by ORIENTEC Co., Ltd.) under an atmosphere at 23° C. and 50% RH. The pulling rate was adjusted to 100 mm/min and the peel angle was adjusted to 180 degrees. The peel strength measured when the peel strength had reached a steady state was taken as an adhesion strength to glass.

The adhesion strength to glass is used as an index of sheet storage stability, and a higher adhesion strength to glass indicates higher sheet storage stability.

### Example 1

An ethylene-vinyl acetate copolymers (EVA-1, produced by Sumitomo Chemical Co., Ltd., KA-40, MFR: 20 g/10 min, content of monomer units derived from vinyl acetate: 28% by mass) (94% by mass of), 6% by mass of an ethylene-vinyl acetate-glycidyl methacrylate copolymer (B-1, produced by Sumitomo Chemical Co., Ltd., BONDFAST 7B, content of monomer units derived from vinyl acetate: 5% by mass, content of monomer units derived from glycidyl methacrylate: 12% by mass), and relative to 100 parts by mass in total of the content of the ethylene-vinyl acetate copolymer and the content of the ethylene-vinyl acetate-glycidyl methacrylate copolymer, 0.1 parts by mass of silicon dioxide (non-calcined amorphous silicon dioxide, CARPLEX #67, produced by Evonik Degussa Japan Co., Ltd., average particle diameter: 8 μm, ignition loss: 4.0%), 0.12 parts by mass of γ-methacryloxypropyltrimethoxysilane (Silquest A-174, produced by Momentive Performance Materials Japan LLC; silane coupling agent), 0.4 parts by mass of tert-butylperoxy-2-ethylhexyl carbonate (PERBUTYL E, produced by NOF Corporation, one-hour half-life temperature: 121° C.; crosslinking agent), 0.9 parts by mass of triallyl isocyanurate (TAIL, produced by Tokyo Chemical Industry Co., Ltd.; crosslinking aid), 0.3 parts by mass of 2-hydroxy-4-n-octoxybenzophenone (Sumisorb 130, produced by Sumika Chemtex Co., Ltd., average particle diameter: 178 μm; UV absorber), and 0.08 parts by mass of bis(2,2,6,6-tetramethyl-4-piperidyl)sebacate (Tinuvin770DF, produced by BASF; light stabilizer) were kneaded for 5 minutes with a Labo Plastomill, subsequently pressing the mixture with a hot presser at 100° C. for 5 minutes under a pressure of 2 MPa, and then cooling it for 5 minutes with a cooling presser at 30° C., to prepare a sheet with a thickness of about 500 μm. The specific volume resistivity, the light transmittance, and the adhesion strength to glass of the resulting sheet were measured and the results are shown in Table 1.

### Example 2

A sheet was prepared and evaluated in the same manner as in Example 1 except that the amount of the ethylene-vinyl acetate copolymer (EVA-1) was changed to 97% by mass and the amount of the ethylene-vinyl acetate-glycidyl methacrylate copolymer (B-1) was changed to 3% by mass. The evaluated results are shown in Table 1.

### Example 3

A sheet was prepared and evaluated in the same manner as in Example 1 except that 6% by mass of an ethylene-methyl acrylate-glycidyl methacrylate copolymer (B-2, produced by Sumitomo Chemical Co., Ltd., BONDFAST 7M, content of monomer units derived from methyl acrylate: 27% by mass, content of monomer units derived from glycidyl methacrylate: 6% by mass) was used instead of 6% by mass of the ethylene-vinyl acetate-glycidyl methacrylate copolymer (B-1). The evaluated results are shown in Table 1.

### Example 4

A sheet was prepared and evaluated in the same manner as in Example 2 except that 3% by mass of an ethylene-methyl acrylate-glycidyl methacrylate copolymer (B-2) was used instead of 3% by mass of the ethylene-vinyl acetate-glycidyl methacrylate copolymer (B-1). The evaluated results are shown in Table 1.

### Example 5

A sheet was prepared and evaluated in the same manner as in Example 4 except that 0.2 parts by mass of silicon dioxide (calcined amorphous silicon dioxide, CARPLEX CS-5, produced by Evonik Degussa Japan Co., Ltd., average particle diameter: 8 μm, ignition loss: 1.7%) was used in addition to 0.1 parts by mass of the silicon dioxide (non-calcined amorphous silicon dioxide, CARPLEX #67, producedby Evonik Degussa Japan Co., Ltd., average particle diameter: 8 μm, ignition loss: 4.0%). The evaluated results are shown in Table 1.

### Example 6

A sheet was prepared and evaluated in the same manner as in Example 1 except that 6% by mass of an ethylene-methacrylic acid copolymer (B-3, produced by DuPont-Mitsui Polychemicals

Co., Ltd., Nucrel N410C, content of monomer units derived from methacrylic acid: 9% by mass) was used instead of 6% by mass of the ethylene-vinyl acetate-glycidyl methacrylate copolymer (B-1). The evaluated results are shown in Table 2.

### Example 7

A sheet was prepared and evaluated in the same manner as in Example 2 except that 3% by mass of an ethylene-methacrylic acid copolymer (B-3, produced by DuPont-Mitsui Polychemicals Co., Ltd., Nucrel N410C, content of monomer units derived from methacrylic acid: 9% by mass) was used instead of 3% by mass of the ethylene-vinyl acetate-glycidyl methacrylate copolymer (B-1). The evaluated results are shown in Table 2.

### Example 8

A sheet was prepared and evaluated in the same manner as in Example 4 except that 0.12 parts by mass of vinyltrimethoxysilane (KBM1001, produced by Shin-Etsu Silicone; silane coupling agent) was used instead of 0.12 parts by mass of the y-methacryloxypropyltrimethoxysilane (Silquest A-174). The evaluated results are shown in Table 2.

### Example 9

A sheet was prepared and evaluated in the same manner as in Example 4 except that 97% by mass of an ethylene-methyl methacrylate copolymer (EMMA-1, produced by Sumitomo Chemical Co., Ltd., WK402, MFR: 20 g/10 min, content of monomer units derived from methyl methacrylate: 25% by mass) was used instead of 97% by mass of the ethylene-vinyl acetate copolymer (EVA-1). The evaluated results are shown in Table 2.

### Comparative Example 1

A sheet was prepared and evaluated in the same manner as in Example 1 except that no ethylene-vinyl acetate-glycidyl methacrylate copolymer (B-1) and no silicon dioxide were used. The evaluated results are shown in Table 3.

### Comparative Example 2

A sheet was prepared and evaluated in the same manner as in Comparative Example 1 except that the amount of γ-methacryloxypropyltrimethoxysilane (Silquest A-174) was changed to 0.25 parts by mass. The evaluated results are shown in Table 3.

### Comparative Example 3

A sheet was prepared and evaluated in the same manner as in Example 1 except that the amount of the ethylene-vinyl acetate copolymer (EVA-1) was changed to 90% by mass and the amount of the ethylene-vinyl acetate-glycidyl methacrylate copolymer (B-1) was changed to 10% by mass. The evaluated results are shown in Table 3.

### Comparative Example 4

A sheet was prepared and evaluated in the same manner as in Example 3 except that the amount of the ethylene-vinyl acetate copolymer (EVA-1) was changed to 99% by mass and the amount of the ethylene-methyl acrylate-glycidyl methacrylate copolymer (B-2) was changed to 1% by mass. The evaluated results are shown in Table 3.

### Comparative Example 5

A sheet was prepared and evaluated in the same manner as in Example 2 except that 3% by mass of an ethylene-ethyl acrylate-maleic anhydride copolymer (B-4, LOTADER AX8390 produced by ARKEMA, content of monomer units derived from ethyl acrylate: 29% by mass (catalog value), content of monomer units derived from maleic anhydride: 1.3% by mass (catalog value)) was used instead of 3% by mass of the ethylene-vinyl acetate-glycidyl methacrylate copolymer (B-1). The evaluated results are shown in Table 4.

### Comparative Example 6

A sheet was prepared and evaluated in the same manner as in Comparative Example 1 except that 100% by mass of an ethylene-methyl methacrylate copolymer (EMMA-1, produced by Sumitomo Chemical Co., Ltd., WK402, MFR: 20 g/10 min, content of monomer units derived from methyl methacrylate: 25% by mass) was used instead of 100% by mass of the ethylene-vinyl acetate copolymer (EVA-1). The evaluated results are shown in Table 4.

TABLE 1

| | | | Examples | | | | |
|---|---|---|---|---|---|---|---|
| | | | 1 | 2 | 3 | 4 | 5 |
| Ethylene-unsaturated ester copolymer | | | EVA-1 | EVA-1 | EVA-1 | EVA-1 | EVA-1 |
| (A) | | | | | | | |
| Content of (A) | | % by mass | 94 | 97 | 94 | 97 | 97 |
| Olefin resin (B) | | | B-1 | B-1 | B-2 | B-2 | B-2 |
| Content of (B) | | % by mass | 6 | 3 | 6 | 3 | 3 |
| Sum total of the contents of | | % by mass | 17 | 17 | 33 | 33 | 33 |
| monomer units other than | | | | | | | |
| ethylene in (B) | | | | | | | |
| Content of silicon dioxide | | parts by | 0.1 | 0.1 | 0.1 | 0.1 | 0.3 |
| | | mass | | | | | (Total) |
| Content of silane coupling agent | | parts by | 0.12 | 0.12 | 0.12 | 0.12 | 0.12 |
| | | mass | | | | | |
| Specific volume resistivity | | Ω · cm | 2 × 10¹⁵ | 2 × 10¹⁵ | 3 × 10¹⁵ | 2 × 10¹⁵ | 4 × 10¹⁵ |
| Adhesion strength to | N/10 mm | 0 hours | 112 | 108 | 109 | 106 | 105 |
| glass | | 1000 | 106 | 104 | 106 | 100 | — |
| [Before or after wet | | hours | | | | | |
| heating test] | | | | | | | |
| Sheet storage stability | N/10 mm | After 3 | — | — | 106 | 104 | 104 |
| [Adhesion strength to | | hours | | | | | |
| glass] | | | | | | | |
| Light transmittance | | % | 91.1 | 91.9 | 92.3 | 92.3 | 92.3 |

TABLE 2

| | | | Examples | | | |
|---|---|---|---|---|---|---|
| | | | 6 | 7 | 8 | 9 |
| Ethylene-unsaturated ester copolymer (A) | | | EVA-1 | EVA-1 | EVA-1 | EMMA-1 |
| Content of (A) | | % by mass | 94 | 97 | 97 | 97 |
| Olefin resin (B) | | | B-3 | B-3 | B-2 | B-2 |
| Content of (B) | | % by mass | 6 | 3 | 3 | 3 |
| Sum total of the contents of | | % by mass | 9 | 9 | 33 | 33 |
| monomer units other than ethylene | | | | | | |
| in (B) | | | | | | |
| Content of silicon dioxide | | parts by | 0.1 | 0.1 | 0.1 | 0.1 |
| | | mass | | | | |
| Content of silane coupling agent | | parts by | 0.12 | 0.12 | 0.12 | 0.12 |
| | | mass | | | | |
| Specific volume resistivity | | Ω · cm | 3 × 10¹⁴ | 3 × 10¹⁴ | 2 × 10¹⁵ | 2 × 10¹⁵ |
| Adhesion strength to glass | N/10 mm | 0 hours | 95 | 94 | 100 | 89 |
| [Before or after wet heating | | 1000 | 116 | 103 | 112 | 84 |
| test] | | hours | | | | |
| Sheet storage stability | N/10 mm | After 3 | 94 | 97 | 101 | 89 |
| [Adhesion strength to | | hours | | | | |
| glass] | | | | | | |
| Light transmittance | | % | 91.1 | 91.9 | 92.4 | 92.0 |

TABLE 3

| | | | Comparative Examples | | | |
|---|---|---|---|---|---|---|
| | | | 1 | 2 | 3 | 4 |
| Ethylene-unsaturated ester copolymer | | | EVA-1 | EVA-1 | EVA-1 | EVA-1 |
| (A) | | | | | | |
| Content of (A) | | % by mass | 100 | 100 | 90 | 99 |
| Olefin resin (B) | | | — | — | B-1 | B-2 |
| Content of (B) | | % by mass | — | — | 10 | 1 |
| Sum total of the contents of | | % by mass | — | — | 17 | 33 |
| monomer units other than | | | | | | |
| ethylene in (B) | | | | | | |
| Content of silicon dioxide | | parts by | 0 | 0 | 0.1 | 0.1 |
| | | mass | | | | |
| Content of silane coupling | | parts by | 0.12 | 0.25 | 0.12 | 0.12 |
| agent | | mass | | | | |
| Specific volume resistivity | | Ω · cm | 2 × 10¹⁴ | 9 × 10¹³ | 2 × 10¹⁵ | 2 × 10¹⁵ |
| Adhesion strength to | N/10 mm | 0 hours | 100 | 103 | — | 102 |
| glass | | 1000 | 73 | 85 | — | 73 |
| [Before or after wet | | hours | | | | |
| heating test] | | | | | | |
| Sheet storage | N/10 mm | After 3 | 83 | 102 | — | 98 |
| stability | | hours | | | | |
| [Adhesion strength to | | | | | | |
| glass] | | | | | | |
| Light transmittance | | % | 92.3 | 92.3 | 87.8 | 92.3 |

TABLE 4

| | | | Comparative | |
|---|---|---|---|---|
| | | | Examples | |
| | | | 5 | 6 |
| Ethylene-unsaturated ester copolymer (A) | | | EVA-1 | EMMA-1 |
| Content of (A) | | % by mass | 97 | 100 |
| Olefin resin (B) | | | B-4 | — |
| Content of (B) | | % by mass | 3 | — |
| Sum total of the contents of monomer | | % by mass | 30.3 | — |
| units other than ethylene in (B) | | | | |
| Content of silicon dioxide | | parts by | 0.1 | 0 |
| | | mass | | |
| Content of silane coupling agent | | parts by | 0.12 | 0.12 |
| | | mass | | |
| Specific volume resistivity | | Ω · cm | 8 × l0¹⁴ | 2 × 10¹⁵ |
| Adhesion strength to | N/10 mm | 0 hours | 82 | 94 |
| glass [Before or | | 1000 hours | 73 | 70 |
| after wet heating test] | | | | |
| Sheet storage stability | N/10 mm | After 3 | 70 | 92 |
| [Adhesion strength to | | hours | | |
| glass] | | | | |

| | | | |
|---|---|---|---|
| Light transmittance | % | 92.3 | 92.3 |

What is claimed is:

1. An encapsulant sheet for a solar cell comprising:
not less than 91% by mass but less than 99% by mass of an ethylene-unsaturated ester copolymer (A) that comprises monomer units derived from ethylene and monomer units derived from at least one unsaturated ester selected from the group consisting of vinyl acetate, vinyl propionate, methyl acrylate, ethyl acrylate, butyl acrylate, methyl methacrylate, and ethyl methacrylate, and that fails to comprise monomer units derived from acrylic acid, methacrylic acid, or any unsaturated carboxylic glycidyl ester, wherein the content of the monomer units derived from ethylene is 60% by mass to 80% by mass and the content of the monomer units derived from the at least one unsaturated ester is 20% by mass to 40% by mass where the content of the monomer units derived from ethylene and the content of the monomer units derived from the at least one unsaturated ester are each relative to the sum total of the two contents being taken as 100% by mass,
more than 1% by mass but not more than 9% by mass of at least one olefin resin (B) selected from the group consisting of an ethylene-(meth) acrylic acid copolymer comprising monomer units derived from ethylene and monomer units derived from acrylic acid or methacrylic acid and an ethylene-unsaturated carboxylic glycidyl ester copolymer comprising monomer units derived from ethylene and monomer units derived from an unsaturated carboxylic glycidyl ester, wherein the content of the ethylene-unsaturated ester copolymer (A) and the content of the at least one olefin resin (B) are each relative to the sum total of the two contents being taken as 100% by mass,
0.001 parts by mass to 5 parts by mass of silicon dioxide, and
0.001 parts by mass to 0.5 parts by mass of a silane coupling agent, wherein the content of the silicon dioxide and the content of the silane coupling agent are each relative to the combined content of the ethylene-unsaturated ester copolymer (A) and the at least one olefin resin (B) being taken as 100% by mass.

2. The encapsulant sheet for a solar cell according to claim 1, wherein the ignition loss of the silicon dioxide is 1.3% to 15%.

3. The encapsulant sheet for a solar cell according to claim 1, wherein the ignition loss of the silicon dioxide is 1.3% to 10%.

4. A solar cell comprising a light-receiving-surface protective member, a solar cell element, a lower protective member, and an encapsulant sheet for a solar cell according to claim 1, wherein the solar cell element encapsulated by the encapsulant sheet is disposed between the light-receiving-surface protective member and the lower protective member.
